(19) United States
(12) Patent Application Publication
(10) Pub. No.: US 2006/0064617 A1
(43) Pub. Date: Mar. 23, 2006

(54) Internal clock generator

(75) Inventor: Bok Rim Ko, Gyeonggi-do (KR)

Correspondence Address: HELLER EHRMAN WHITE & MCAULIFFE LLP, 1717 RHODE ISLAND AVE, NW, WASHINGTON, DC, 20036-3001, US

(73) Assignee: Hynix Semiconductor Inc., Gyeonggi-do (KR)

(21) Appl. No.: 11/170,438

(22) Filed: Jun. 30, 2005

(30) Foreign Application Priority Data
Sep. 20, 2004 (KR) 10-2004-0075161

(51) Int. Cl. G01R 31/28

(52) U.S. Cl. 714/731

(57) ABSTRACT

An internal clock generator comprises delay units adapted and configured to delay a first clock outputted from a clock buffer for predetermined delay times to output a plurality of second clocks, respectively, clock pulse generating units adapted and configured to generate clock pulses depending on the plurality of second clocks, respectively and a clock synthesizer adapted and configured to synthesize the clock pulses to generate an internal clock. As a result, a clock frequency of test equipment is internally increased at a wafer level test mode, thereby performing a high-speed test and reducing a test cost.

### BACKGROUND OF THE INVENTION

1. Field of the Invention

The present invention generally relates to an internal clock generator of a semiconductor memory device, and more specifically, to a technology of internally increasing a clock frequency of test equipment in a wafer level test to facilitate a high-speed test and reduce a test cost.

2. Description of the Related Art

A chip test of a semiconductor memory device includes a test performed at a wafer state and a test performed at a package state.

Generally, many test items are performed at the wafer level test and a clock of a test equipment has a cycle of 20˜30 ns. As a result, since a high-speed test item cannot be tested at the wafer state, it is performed at a package state.

Although the high-speed test item has to be performed is tested at the wafer level when a MCP (Multi Chip Package) is applied, the high-speed test item is not performed at the wafer level because a speed of test equipment has a limit.

A general semiconductor memory device generates an external clock into an internal clock pulse through a clock buffer. Since a frequency of the internal clock pulse is identical with that of the external clock, the high-speed test item test is not performed.

### SUMMARY OF THE INVENTION

It is an object of the present invention to generate an internal clock having a frequency that is higher than that of an external clock, thereby performing a high-speed test item.

It is another object of the present invention to generate an internal clock having a frequency that is higher than that of an external clock, thereby reducing a test time.

It is still another object of the present invention to generate an internal clock having a frequency that is higher than that of an external clock, thereby reducing a product cost.

According to one embodiment of the present invention, an internal clock generator comprises a clock buffer adapted and configured to set a level of a first clock at a level suitable for an internal circuit depending on an external clock, delay units adapted and configured to delay the first clock for predetermined delay times to generate a plurality of second clocks, respectively, clock pulse generating units adapted and configured to generate clock pulses depending on the plurality of second clocks, respectively, and a clock synthesizer adapted and configured to synthesize the clock pulses to generate an internal clock.

According to another embodiment of the present invention, an internal clock generator comprises a clock buffer adapted and configured to set a level of a first clock at a level suitable for an internal circuit depending on an external clock, delay units adapted and configured to sequentially delay the first clock to generate a plurality of second clocks, clock pulse generating units adapted and configured to generate clock pulses depending on the plurality of second clocks; and a clock synthesizer adapted and configured to synthesize the clock pulses to generate an internal clock.

According to still another embodiment of the present invention, an internal clock generator comprises a clock buffer adapted and configured to set a level of a first clock at a level suitable for an internal circuit depending on an external clock, a clock pulse generating unit adapted and configured to generate a first clock pulse depending on the first clock, delay units adapted and configured to sequentially delay the first clock pulse for determined delay times to generate the plurality of second clock pulses, respectively, and a clock synthesizer adapted and configured to synthesize the clock pulses to generate an internal clock.

### BRIEF DESCRIPTION OF THE DRAWINGS

Other aspects and advantages of the present invention will become apparent upon reading the following detailed description and upon reference to the drawings in which:

FIG. 1 is a block diagram illustrating an internal clock generator according to an embodiment of the present invention;

FIG. 2 is a block diagram illustrating an internal clock generator according to another embodiment of the present invention;

FIG. 3 is a block diagram illustrating an internal clock generator according to still another embodiment of the present invention;

FIG. 4 is a circuit diagram illustrating a delay unit shown in FIGS. 1, 2 and 3;

FIG. 5 is a circuit diagram illustrating a clock pulse generating unit shown in FIGS. 1 and 2;

FIG. 6 is a block diagram illustrating an internal clock generator according to still another embodiment of the present invention;

FIG. 7 is a block diagram illustrating an internal clock generator according to still another embodiment of the present invention;

FIG. 8 is a block diagram illustrating an internal clock generator according to still another embodiment of the present invention;

FIG. 9 is a circuit diagram illustrating a delay unit shown in FIGS. 6, 7 and 8;

FIG. 10 is a circuit diagram illustrating a delay control signal generator shown in FIGS. 6, 7 and 8;

FIG. 11 is a timing diagram illustrating the operation of the internal clock generator shown in FIGS. 1, 2, 6 and 7; and

FIGS. 12 is a timing diagram illustrating the operation of the internal clock generator shown in FIGS. 3 and 8.

### DETAILED DESCRIPTION OF THE EXEMPLARY EMBODIMENTS

The present invention will be described in detail with reference to the accompanying drawings. Wherever possible, the same reference numbers will be used throughout the drawings to refer to the same or like parts.

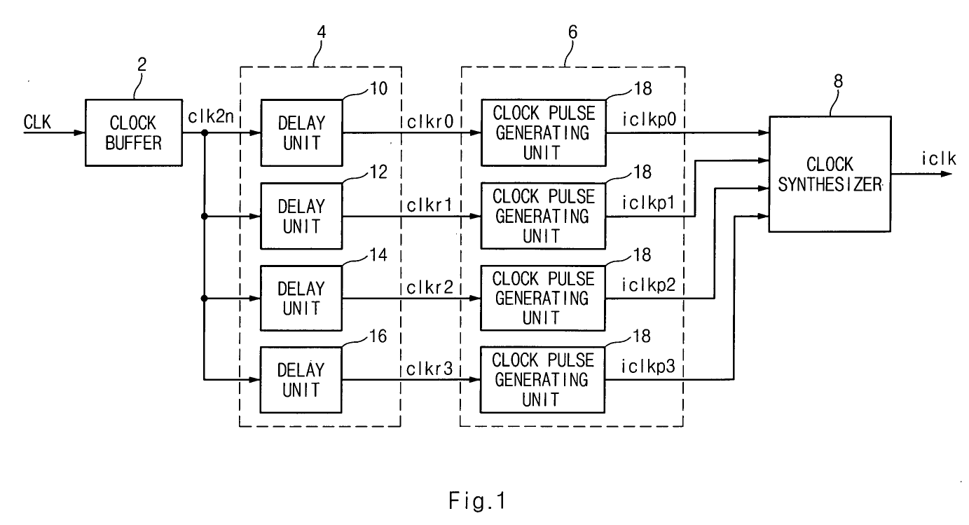

FIG. 1 is a block diagram illustrating an internal clock generator according to an embodiment of the present invention.

In this embodiment, an internal clock generator comprises a clock buffer 2, a delay block 4, a clock pulse generator 6 and a clock synthesizer 8.

The clock buffer 2 buffers an external clock CLK set at a VIL/VIH level (or Low/High level set in a Spec) to be at a level suitable for an internal circuit. Preferably, the clock buffer is static (when an interface input signal is applied at a LVTTL level) or a differential amplifier type (when an input signal is applied at a SSTL or SSTL2 level).

The delay block 4 includes delay units 10, 12, 14 and 16 which delay clock clk2n outputted from the clock buffer 2 each for different delay times to generate clocks clkr0˜clkr3 which have sequential rising edge timings. Here, the delay unit 10 sets the shortest delay path not to generate an unnecessary delay. Preferably, a delay time of the delay unit 12 is set to be ¼ tCK of a clock used in test equipment, and the delay units 14 and 16 have a delay time two and three times longer than that of the delay unit 12, respectively.

The clock pulse generator 6 includes clock pulse generating units 18 which generate clock pulses iclkp0˜iclkp3 respectively at rising edges of the clocks clkr0˜clkr3 outputted from the delay block 4. Preferably, the clock pulses iclkp0˜iclkp3 are included in one cycle of the external clock CLK.

The clock synthesizer 8 synthesizes clock pulses iclkp0˜iclkp3 outputted from the clock pulse generator 6 to generate an internal clock iclk.

In this embodiment, the internal clock generator is configured to generate four pulses for one cycle of the external clock CLK using the four delay units. However, the number of generated pulses can be regulated by adjusting the number of delay units, so that a cycle of the internal clock iclk is regulated.

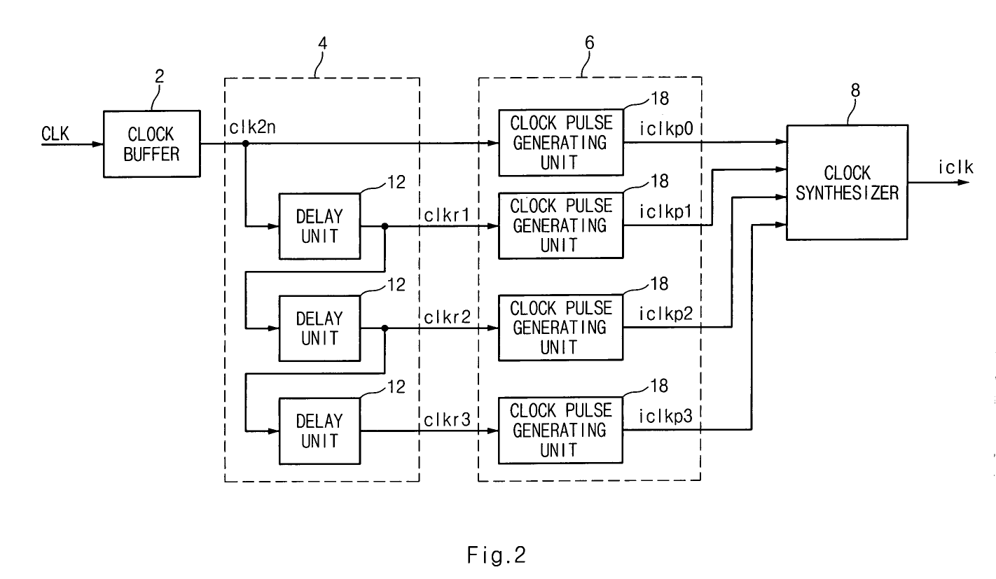

FIG. 2 is a block diagram illustrating an internal clock generator according to another embodiment of the present invention.

In this embodiment, an internal clock generator comprises a clock buffer 2, a delay block 4, a clock pulse generator 6 and a clock synthesizer 8.

The clock buffer 2 buffers an external clock CLK to be set at a level suitable for an internal circuit.

The delay block 4 includes delay units 12 which sequentially delay clocks clk2n outputted from the clock buffer 2 to generate clocks clkr1˜clkr3 which have sequential rising edge timings. Preferably, the delay units 12 have the same delay time.

The clock pulse generator 6 includes clock pulse generating units 18 which generate clock pulses iclkp0˜iclkp3 respectively at rising edges of the clock clk2n outputted from the clock buffer 2 and the clocks clkr1˜clkr3 outputted from the delay block 4. Here, the clock pulses iclkp0˜iclkp3 are required to be included in one cycle of the external clock CLK.

The clock synthesizer 8 synthesizes the clock pulses iclkp0˜iclkp3 outputted from the clock pulse generator 6 to generate an internal clock iclk.

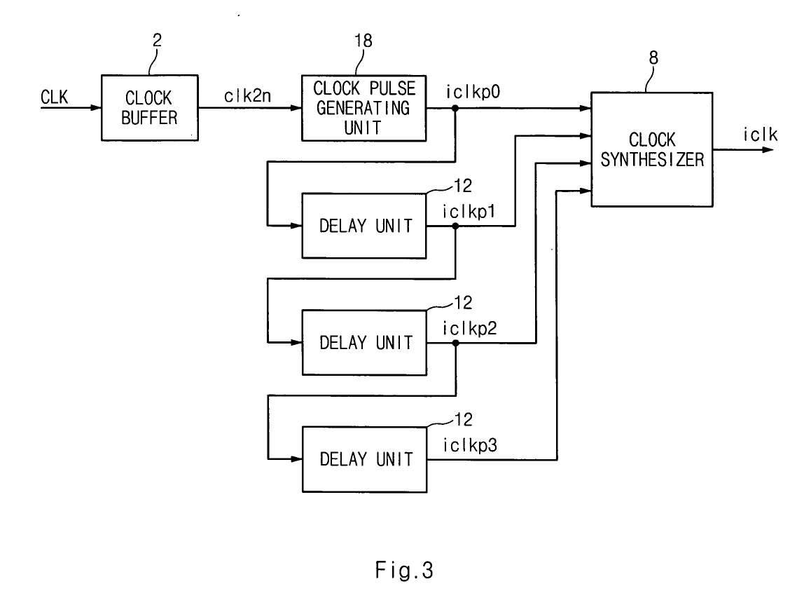

FIG. 3 is a block diagram illustrating an internal clock generator according to still another embodiment of the present invention.

In this embodiment, an internal clock generator comprises a clock buffer 2, a clock pulse generating unit 18, delay units 12 and a clock synthesizer 8.

The clock buffer 2 buffers an external clock CLK to be set at a level suitable for an internal circuit.

The clock pulse generating unit 18 generates a clock pulse iclkp0 at a rising edge of a clock clk2n outputted from the clock buffer 2.

The delay units 12 sequentially delays the clock pulse iclkp0 outputted from the clock pulse generating unit 18 to generate clock pulses iclkp1˜iclkp3. Preferably, the delay units 12 have the same delay time. The clock pulses iclkp0˜iclkp3 are required to be included in one cycle of the external clock CLK.

The clock synthesizer 8 synthesizes the clock pulses iclkp0˜iclkp3 outputted from a clock pulse generating block 6 to generate an internal clock iclk.

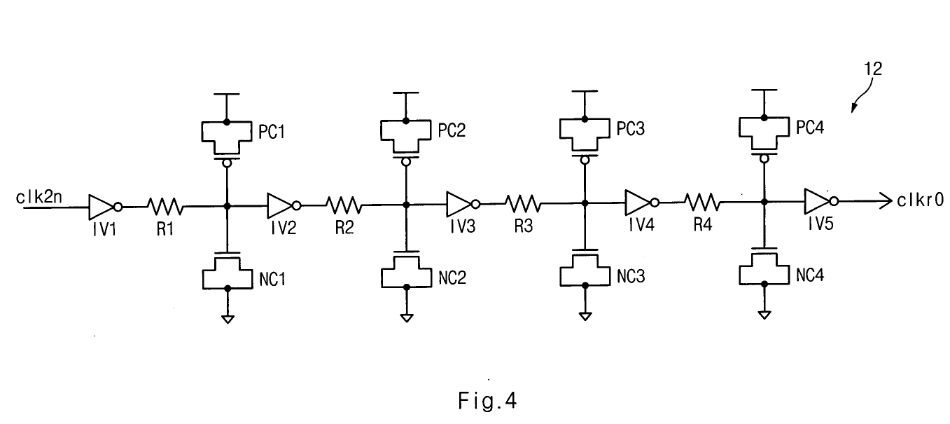

FIG. 4 is a circuit diagram illustrating the delay unit 12 shown in FIGS. 1, 2 and 3.

The delay unit 12 comprises inverters IV1˜IV5, resistors R1˜R4, NMOS-type capacitors NC1˜NC4, and PMOS-type capacitors PC1˜PC4.

The inverters IV1˜IV5 and the resistors R1˜R4 are alternately connected in serial. The NMOS-type capacitors NC1˜NC4 and the PMOS-type capacitors PC1˜PC4 are connected to common nodes of input terminals of the resistors R1˜R4 and the inverters IV2˜IV5, respectively.

Here, the number of the inverters IV1˜IV5, the resistors R1˜R4, the NMOS-type capacitors NC1˜NC4 and the PMOS-type capacitors PC1˜PC4 can be added or reduced to regulated a delay time. Also, a type of the delay unit 12 can be changed if necessary.

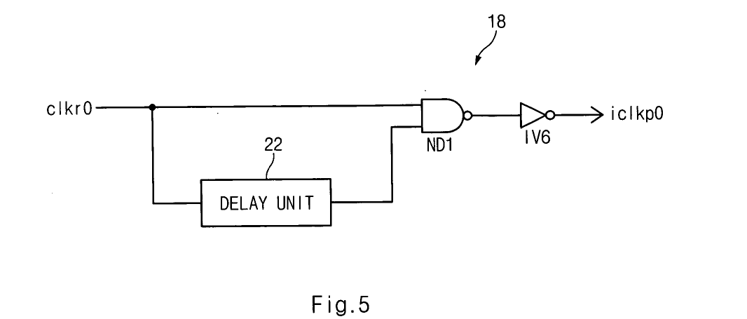

FIG. 5 is a circuit diagram illustrating the clock pulse generating unit 18 shown in FIGS. 1 and 2.

The clock pulse generating unit 18 comprises a delay unit 22, a NAND gate ND1 and an inverter IV6.

The delay unit 22 delays the clock clkr0 outputted from the delay unit 10 shown in FIGS. 1 and 2 for a predetermined time.

The NAND gate ND1 performs a NAND operation on the clock clkr0 and an output signal from the delay unit 22. The inverter IV6 inverts an output signal from the NAND gate ND1 to generate the clock pulse iclkp0.

Although the clock pulse generating unit 18 of FIG. 3 has the same components as those of the clock pulse generating unit 18 of FIG. 5, there is a difference in that the clock pulse generating unit 18 of FIG. 3 receives the clock clk2n outputted from the clock buffer 2 to generate the clock pulse iclkp0.

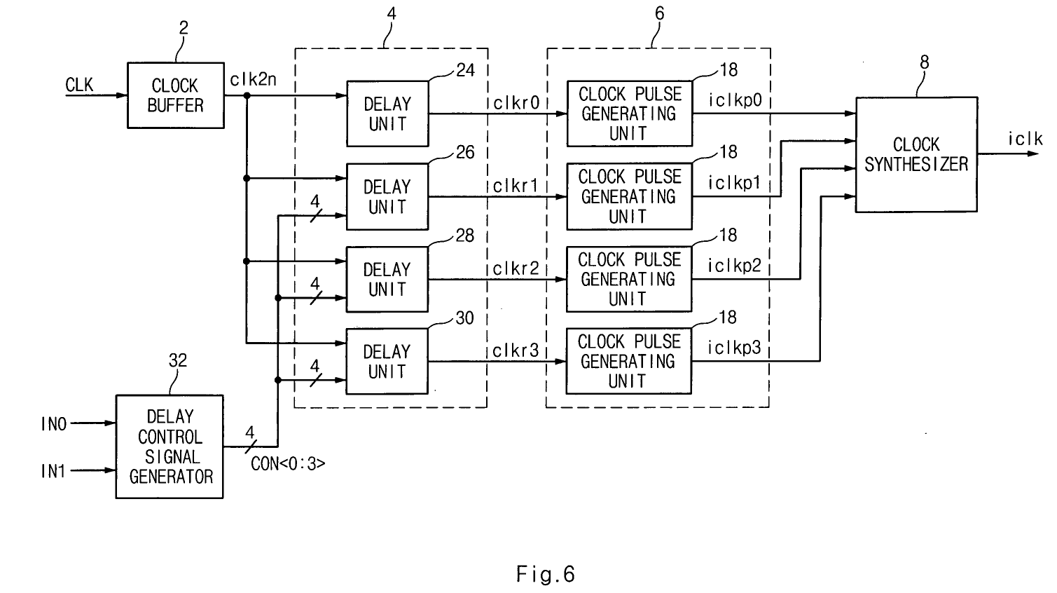

FIG. 6 is a block diagram illustrating an internal clock generator according to still another embodiment of the present invention.

In this embodiment, an internal clock generator comprises a clock buffer 2, a delay block 4, a clock pulse generator 6, a clock synthesizer 8 and a delay control signal generator 32.

The clock buffer 2 buffers an external clock CLK to be set at a level suitable for an internal circuit.

The delay block 4 comprises delay units 24, 26, 28 and 30 which delay a clock clk2n outputted from the clock buffer 2 for different delay times to generate clocks clkr0˜clkr3 which have sequential rising edges. Here, each delay time of the delay units 26, 28 and 30 is regulated in response to a delay control signal CON<0:3>. The delay unit 24 set the shortest delay path not to generate an unnecessary delay if possible. Preferably, the delay units 28 and 30 have a delay time two and three times longer than that of the delay unit 26, respectively.

The clock pulse generator 6 includes clock pulse generating units 18 which generate clock pulses iclkp0˜iclkp3 respectively at rising edges of the clocks clkr0˜clkr3 outputted from the delay block 4. Here, the clock pulses iclkp0˜iclkp3 are required to be included in one cycle of the external clock CLK.

The clock synthesizer 8 synthesizes the clock pulses iclkp0˜iclkp3 outputted from the clock pulse generator 6 to generate an internal clock iclk.

The delay control signal generator 32 codes input addresses IN0 and IN1 to generate delay control signals CON0˜CON3. The delay control signals CON0˜CON3 regulate a delay time of the delay block 4 through a test mode to cope with change of a tCK of test equipment corresponding to the external clock CLK while a test is performed so as to change an internal clock interval.

In this embodiment, the internal clock generator is configured to generate four pulses for one cycle of the external clock CLK using the four delay units. However, the number of generated pulses can be regulated by adjusting the number of delay units, so that a cycle of the internal clock iclk is regulated.

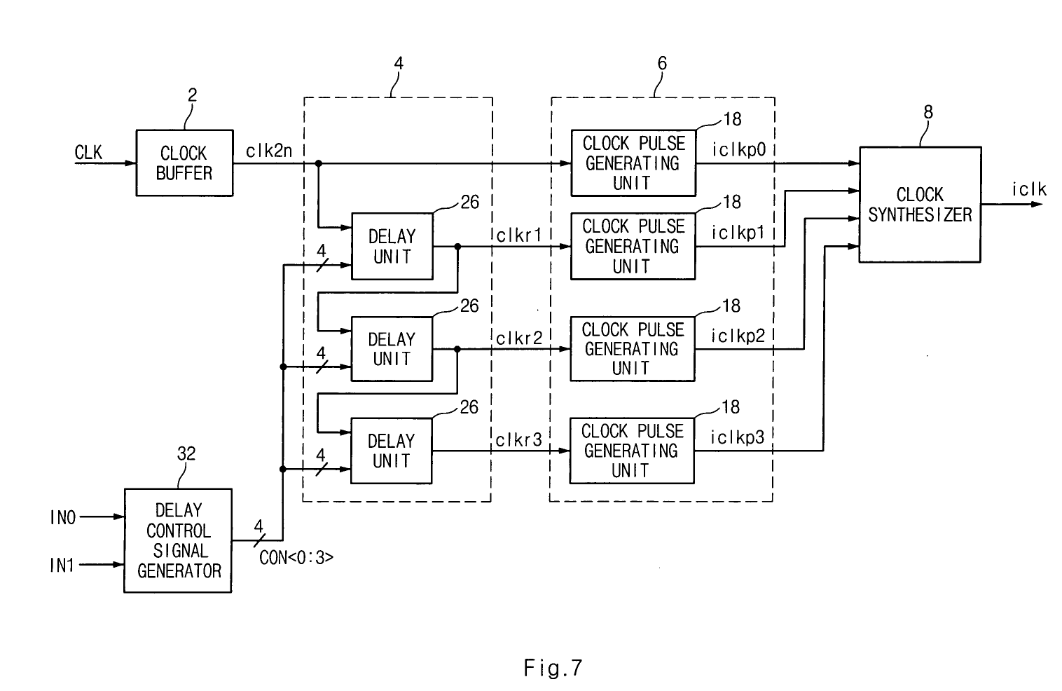

FIG. 7 is a block diagram illustrating an internal clock generator according to still another embodiment of the present invention.

In this embodiment, an internal clock generator comprises a clock buffer 2, a delay block 4, a clock pulse generator 6, a clock synthesizer 8 and a delay control signal generator 32.

The clock buffer 2 buffers an external clock CLK to be set at a level suitable for an internal circuit.

The delay block 4 includes delay units 26 which sequentially delay a clock clk2n outputted from the clock buffer 2 to generate clocks clkr1˜clkr3 which have sequential rising edge timings. Preferably, each delay time of the delay units 26 is regulated in response to a delay control signal CON<0:3>, and the delay units 26 have the same delay time.

The clock pulse generator 6 includes clock pulse generating units 18 which generate clock pulses iclkp0˜iclkp3 respectively at rising edges of the clock clk2n outputted from the clock buffer 2 and the clocks clkr1˜clkr3 outputted from the delay block 4. Preferably, the clock pulses iclkp0˜iclkp3 are included in one cycle of the external clock CLK.

The clock synthesizer 8 synthesizes clock pulses iclkp0˜iclkp3 outputted from the clock pulse generator 6 to generate an internal clock iclk.

The delay control signal generator 32 decodes addresses IN0 and IN1 to generate delay control signals CON0˜CON3.

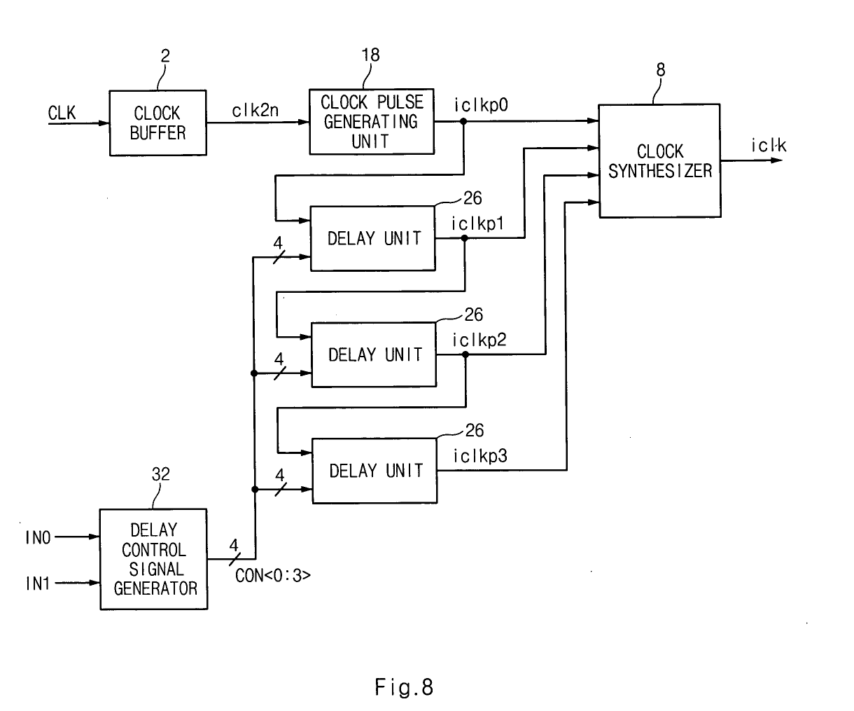

FIG. 8 is a block diagram illustrating an internal clock generator according to still another embodiment of the present invention.

In this embodiment, an internal clock generator comprises a clock buffer 2, a clock pulse generator 18, delay units 26, a clock synthesizer 8 and a delay control signal generator 32.

The clock buffer 2 buffers an external clock CLK to be set at a level suitable for an internal circuit.

The clock pulse generator 18 generates a clock pulse iclkp0 at a rising edge of a clock clk2n outputted from the clock buffer 2.

The delay units 26 sequentially delays the clock pulse iclkp0 outputted from the clock pulse generator 18 to generate clock pulses iclkp1˜iclkp3. Preferably, the delay units 26 have the same delay time. Also, the clock pulses iclkp0˜iclkp3 are included in one cycle of the external clock CLK.

The clock synthesizer 8 synthesizes the clock pulses iclkp0˜iclkp3 outputted from a clock pulse generator 18 to generate an internal clock iclk.

The delay control signal generator 32 decodes input addresses IN0 and IN1 to generate delay control signals CON0˜CON3.

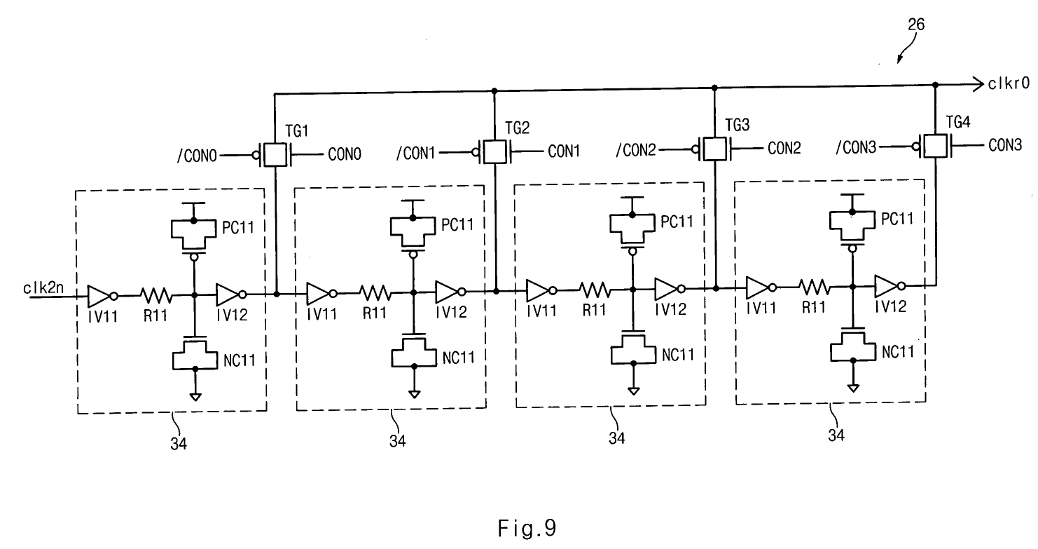

FIG. 9 is a circuit diagram illustrating the delay unit 26 shown in FIGS. 6, 7 and 8.

The delay unit 26 comprises unit delay units 34 and transmission gates TG1˜TG4.

Each unit delay unit 34 comprises inverters IV11 and IV12, a resistor R11, a NMOS-type capacitor NC11 and a PMOS-type capacitor PC11.

The inverters IV11, IV12 and the resistor R11 are alternately connected in serial. The NMOS-type capacitor NC11 and the PMOS-type capacitor PC11 are connected to an output terminal of the unit delay unit 34.

The transmission gates TG1 and TG4 selectively transmit output signals from the unit delay units 34 in response to the delay control signals CON0˜CON3, respectively.

As a result, the delay time of the delay unit 26 is regulated in response to the delay control signals CON0˜CON3 generated by coding of the input addresses IN0 and IN1 at a test mode.

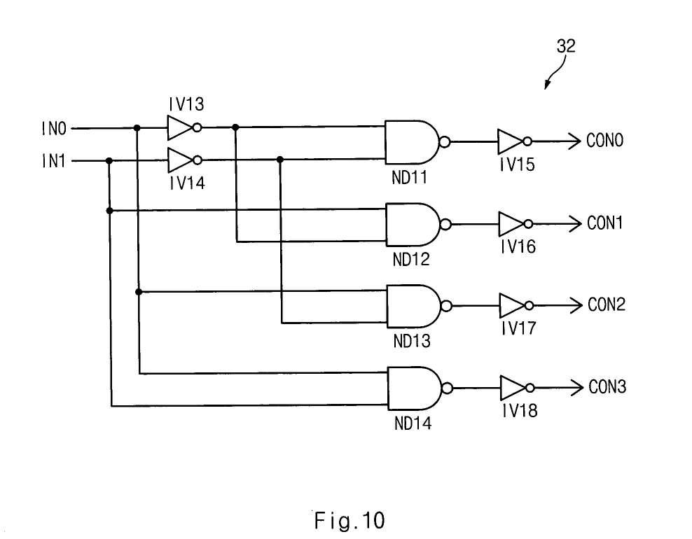

FIG. 10 is a circuit diagram illustrating the delay control signal generator 32 shown in FIGS. 6, 7 and 8.

The delay control signal generator 32 comprises inverters IV13˜IV18, and NAND gates ND11˜ND14.

The inverters IV13 and IV14 invert the input addresses IN0 and IN1, respectively.

The NAND gate ND11 performs a NAND operation on output signals from the inverters IV13 and IV14. The NAND gate ND12 performs a NAND operation on the output signal from the inverter IV13 and the input address IN1. The NAND gate ND13 performs a NAND operation on the input address IN0 and the output signal from the inverter IV14. The NAND gate ND14 performs a NAND operation on the input addresses IN0 and IN1.

The inverters IV15˜IV18 invert output signals from the NAND gates ND11˜ND14 to generate the delay control signals CON0˜CON3, respectively.

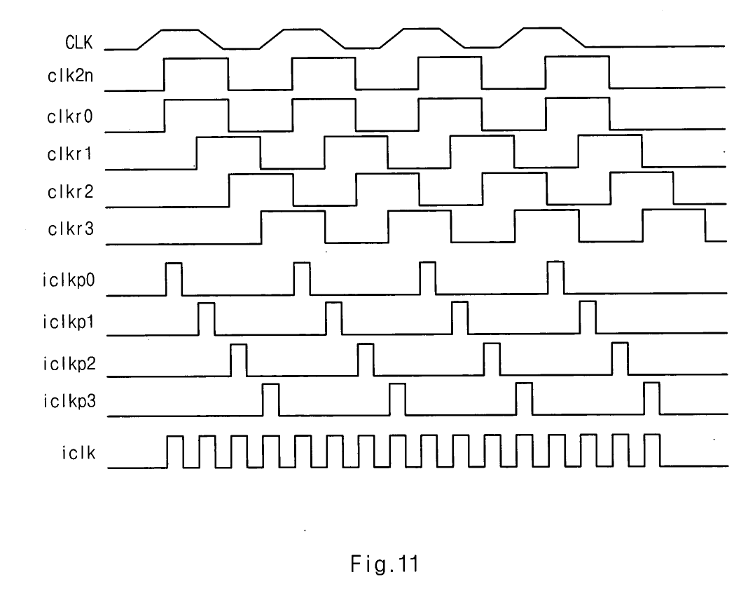

FIG. 11 is a timing diagram illustrating the operation of the internal clock generator shown in FIGS. 1, 2, 6 and 7.

The clock clk2n is buffered so that the external clock CLK set at a VIL/VIH level (or Low/High level set at a Spec) may be set at a level suitable for an internal circuit by the clock buffer 2.

The clocks clkr0˜clkr3 are obtained by sequentially delaying the clock clk2n by the delay block 4 to have sequential rising edges.

The clock pulses iclkp0˜iclkp3 are generated at rising edges of the clocks clkr0˜clkr3 in the clock generator 6.

The internal clock iclk is obtained by synthesizing the clock pulses iclkp0˜iclkp3 by the clock synthesizer 8 to have a predetermined cycle.

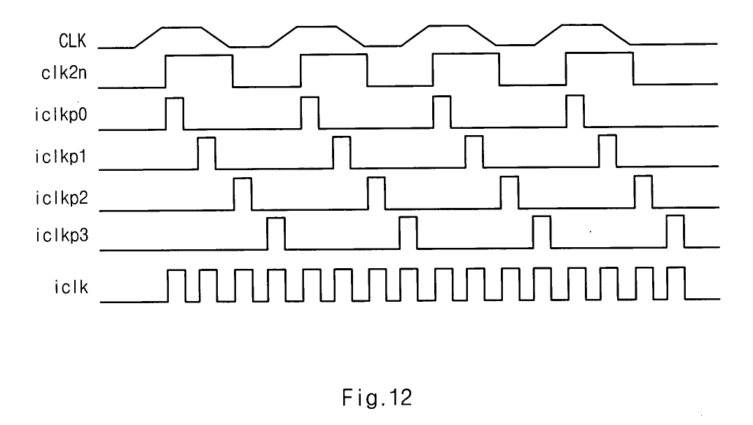

FIG. 12 is a timing diagram illustrating the operation of the internal clock generator shown in FIGS. 3 and 8.

The clock clk2n is obtained by buffering the external clock CLK by the clock buffer 2.

The clock pulse iclkp0 is generated synchronously with respect to the rising edge of the clock clk2n in the clock pulse generating unit 18.

The clock pulses iclkp1˜iclkp3 are obtained by sequentially delaying the clock pulse the iclkp0 by the delay units 26.

The internal clock iclk is obtained by synthesizing the clock pulses iclkp0˜iclkp3 in the clock synthesizer 8 to have a predetermined cycle.

Since the internal clock iclk has four pulses in one cycle tCK of the external CLK, a frequency of the internal clock iclk is four times higher than that of the external clock CLK. The frequency of the internal clock iclk is added or reduced depending on the number of the clock pulses iclkp0˜iclkp3 generated by the clock pulse generator 6.

Preferably, all clock pulses generated by the clock pulse generator 6 are required to be included in one cycle tCK of the eternal clock CLK, and a pulse width of the clock pulse is set to be a half of a reference delay time of the delay unit 12 or 26.

As described above, an internal clock generator according to an embodiment of the present invention is configured to generate a frequency higher than that used in test equipment. Also, in the internal clock generator, test on a high-speed test item is performed at a wafer level, and a wafer test time is reduced. Additionally, a high-speed fail screen is possible at the wafer level, thereby reducing a product cost.

The foregoing description of various embodiments of the invention has been presented for purposes of illustrating and description. It is not intended to be exhaustive or to limit the invention to the precise form disclosed, and modifications and variations are possible in light of the above teachings or may be acquired from practice of the invention. Thus, the embodiments were chosen and described in order to explain the principles of the invention and its practical application to enable one skilled in the art to utilize the invention in various embodiments and with various modifications as are suited to the particular use contemplated.

What is claimed is:

1. An internal clock generator comprising:
a clock buffer adapted and configured to set a level of a first clock at a level suitable for an internal circuit depending on an external clock;
delay units adapted and configured to delay the first clock for predetermined delay times to generate a plurality of second clocks, respectively;
clock pulse generating units adapted and configured to generate clock pulses depending on the plurality of second clocks, respectively; and
a clock synthesizer adapted and configured to synthesize the clock pulses to generate an internal clock.

2. The internal clock generator according to claim 1, wherein a delay time of the delay unit is a multiple of a cycle of the internal clock.

3. The internal clock generator according to claim 1, wherein a pulse width of the clock pulses is a half of one cycle of the internal clock.

4. The internal clock generator according to claim 1, wherein the clock pulses are all included in one cycle of the external clock.

5. The internal clock generator according to claim 1, wherein the number of the clock pulses corresponds to a frequency multiple of the internal clock to the external clock.

6. The internal clock generator according to claim 1, wherein a delay time of the delay units is regulated in response to an address inputted externally at a test mode.

7. The internal clock generator according to claim 6, wherein each of the delay units further comprises:
a plurality of unit delay units connected serially; and
a transmission unit adapted and configured to selectively transmit output signals from the plurality of unit delay units in response to the address.

8. The internal clock generator according to claim 7, further comprising a decoding unit adapted and configured to decode the address.

9. An internal clock generator comprising:
a clock buffer adapted and configured to set a level of a first clock at a level suitable for an internal circuit depending on an external clock;
delay units adapted and configured to sequentially delay the first clock to generate a plurality of second clocks;
clock pulse generating units adapted and configured to generate clock pulses depending on the plurality of second clocks; and
a clock synthesizer adapted and configured to synthesize the clock pulses to generate an internal clock.

10. The internal clock generator according to claim 9, wherein a delay time of the delay unit is a multiple of a cycle of the internal clock.

11. The internal clock generator according to claim 9, wherein a pulse width of the clock pulses is a half of one cycle of the internal clock.

12. The internal clock generator according to claim 9, wherein the clock pulses are all included in one cycle of the external clock.

13. The internal clock generator according to claim 9, wherein the number of the clock pulses corresponds to a frequency multiple of the internal clock to the external clock.

14. The internal clock generator according to claim 9, wherein delay times of the delay units are regulated in response to an address inputted externally at a test mode.

15. The internal clock generator according to claim 14, wherein each of the delay units further comprises:
a plurality of unit delay units connected serially; and
a transmission unit adapted and configured to selectively transmit output signals from the plurality of unit delay units in response to the address.

16. The internal clock generator according to claim 15, further comprising a decoding unit adapted and configured to decode the address.

17. An internal clock generator comprising:
a clock buffer adapted and configured to set a level of a first clock at a level suitable for an internal circuit depending on an external clock;
a clock pulse generating unit adapted and configured to generate a first clock pulse depending on the first clock;
delay units adapted and configured to sequentially delay the first clock pulse for determined delay times to generate the plurality of second clock pulses, respectively; and
a clock synthesizer adapted and configured to synthesize the clock pulses to generate an internal clock.

18. The internal clock generator according to claim 17, wherein a delay time of the delay unit is a multiple of a cycle of the internal clock.

19. The internal clock generator according to claim 17, wherein a pulse width of the clock pulses is a half of one cycle of the internal clock.

20. The internal clock generator according to claim 17, wherein the clock pulses are all included in one cycle of the external clock.

21. The internal clock generator according to claim 17, wherein the number of the clock pulses corresponds to a frequency multiple of the internal clock to the external clock.

22. The internal clock generator according to claim 17, wherein a delay time of the delay units is regulated in response to an address inputted externally at a test mode.

23. The internal clock generator according to claim 22, wherein each of the delay units further comprises:
a plurality of unit delay units connected serially; and
a transmission unit adapted and configured to selectively transmit output signals from the plurality of unit delay units in response to the address.

24. The internal clock generator according to claim 23, further comprising a decoding unit adapted and configured to decode the address.
